(19) United States
(12) Patent Application Publication
(10) Pub. No.: US 2022/0149232 A1
(43) Pub. Date: May 12, 2022

(54) FLUORESCENT SUBSTRATE FOR PRINTED MICRO LEDS

(71) Applicant: Nthdegree Technologies Worldwide Inc., Tempe, AZ (US)

(72) Inventor: William J. Ray, Fountain Hills, AZ (US)

(21) Appl. No.: 17/513,853

(22) Filed: Oct. 28, 2021

Related U.S. Application Data
(60) Provisional application No. 63/111,977, filed on Nov. 10, 2020.

(51) Int. Cl. H01L 33/00; H01L 27/15; H01L 33/50

(52) U.S. Cl. CPC H01L 33/0095; H01L 2933/0041; H01L 33/502; H01L 27/153

(57) ABSTRACT

A light emitting structure uses an extruded mixture of a fluorescent material and a transparent plastic to form a thin flexible substrate. The extrusion, using a slot die, forms a thin flexible film having very smooth surfaces with a uniform thickness. A transparent first conductive layer is then printed over the substrate. Pre-formed micro-LEDs are then printed over the first conductive layer, where the bottom electrodes of the LEDs contact the first conductive layer. A dielectric layer is deposited between the LEDs and exposes the top electrode of the LEDs. A second conductive layer, which may be transparent or reflective, is printed over the LEDs to electrically connect at least some of the LEDs in parallel. Primary light emitted from the LEDs energizes the fluorescent material in the substrate to emit secondary light from the substrate. Blue LED light may combine with the secondary light to create a wide gamut of colors, such as white.

### CROSS-REFERENCE TO RELATED APPLICATIONS

This application is based on U.S. provisional application Ser. No. 63/111,977, filed Nov. 10, 2020, assigned to the present assignee and incorporated herein by reference.

### FIELD OF THE INVENTION

This invention relates to printing pre-formed micro-light emitting diodes (LEDs) over a substrate and converting the primary LED wavelength (blue or UV) to a secondary wavelength and, in particular, to forming the substrate out of fluorescent materials.

### BACKGROUND

It is known, by the present assignee's own work, how to form and print microscopic 2-terminal vertical light emitting diodes (LEDs), with the proper orientation, on a conductive substrate and connect the LEDs in parallel to form a light sheet. Details of such printing of LEDs can be found in U.S. Pat. No. 8,852,467, entitled, Method of Manufacturing a Printable Composition of Liquid or Gel Suspension of Diodes, assigned to the present assignee and incorporated herein by reference.

The substrate is typically a thin polymer sheet having a conductive layer over it. LEDs are printed over the conductive layer so the bottom electrode of the LEDs contacts the conductive layer. A thin dielectric layer is then deposited over the LEDs and conductive layer, while exposing the top LED electrode. A second conductive layer is then printed over the LEDs and dielectric layer for connecting the LEDs in parallel. One or both of the conductive layers is transparent. For wavelength conversion, printed blue or UV LEDs have printed over them a phosphor, a dye, or quantum dots (collectively referred to as fluorescent materials) to convert the blue or UV light to, for example, white light. The result is a flexible light sheet that can take any form.

Problems with fluorescent materials include reduced lifetimes and color shifting due to heat, UV, and moisture. A deposited fluorescent sheet may also be brittle, limiting the flexibility of the light sheet. Secondly, separately providing a substrate and a layer of fluorescent material adds material expense and processing expense. Thirdly, printing a fluorescent layer over the LEDs inherently results in a fluorescent layer that is not precisely flat and not uniformly thick, resulting in non-uniform color emission due to the varying thickness of the fluorescent material.

What is needed is a light emitting structure and a process for forming the light emitting structure, using printed micro-LEDs and a fluorescent material, that does not result in any of the above-mentioned drawbacks.

### SUMMARY

In one embodiment, a fluorescent material, such as organic dyes (in dry crystal form), inorganic phosphors, perovskite crystals, or quantum dots, is mixed with a transparent plastic material in a hopper of an extrusion machine. A slot die is used to extrude a very precise thin film formed of the fluorescent material encased in the transparent plastic. Thus, the fluorescent material is protected from humidity and is extremely uniform in density and thickness. This film will then be used as a substrate for printed micro-LEDs. In one example, red, green, and blue dyes, or a YAG (yellow/green) phosphor, may be used for creating white light. If blue light from the LEDs is intended to leak through the fluorescent substrate, no blue fluorescent material is needed.

Next, a transparent conductor, such as silver nano-wire ink, is deposited over the substrate and cured to form a thin conductive layer. During curing, the nano-wire ink solvent is evaporated by heat, and the nano-wires are sintered to create a semi-transparent conductive mesh.

Blue or UV micro-LEDs are suspended in a printable medium, such as alcohol, to form an LED ink and then printed over the conductive layer so, after a curing step, the “bottom” electrodes of the LEDs electrically contact the conductive layer.

A thin dielectric layer is then deposited over the conductive layer and the LEDs so that the top electrodes of the LEDs are exposed.

A top conductive layer is then deposited and cured to electrically connect the LEDs in parallel. The top conductive layer may be transparent or reflective, or a separate reflective layer is deposited over the top of the structure so all the LED light is directed toward the substrate.

The substrate wavelength-converts the primary LED light to create any color emission. Since the fluorescent material in the substrate is uniformly distributed and the thickness is extremely uniform, the color uniformity is higher than if the fluorescent materials were deposited in a conventional way. The fluorescent material is protected from humidity, and any heat produced by the LEDs is somewhat diffused by the plastic encasing the fluorescent materials. The plastic also somewhat helps to mix the light, improving color uniformity.

Accordingly, no separate transparent substrate is used, and the “fluorescent substrate” creates synergy since, not only is one layer eliminated in the light generating structure, but the fluorescent substrate provides improved wavelength conversion.

The use of the invention with fluorescent dyes is particularly valuable since organic dyes have a higher quantum efficiency (>80%) compared to phosphors and quantum dots and can better tolerate heat. Perovskite nano-crystals also show great promise due to their high quantum efficiency.

Although the invention is described in the context of printing pre-formed micro LEDs, the LEDs may instead be printed layered structures over the fluorescent substrate.

Other embodiments are disclosed.

### BRIEF DESCRIPTION OF THE DRAWINGS

FIG. 1 is a cross-sectional view of a small portion of a light sheet in accordance with one embodiment of the invention. Two LEDs are shown with the proper orientation, and another LED is shown with improper orientation.

FIG. 2 illustrates the bottom electrode (facing the fluorescent substrate) of one form of a printable inorganic LED die that generally orients itself downward when printing.

FIG. 3 is a cross-section of the LED of FIG. 2 showing how light is emitted from the top, bottom, and sides of the LED in a generally Lambertian manner.

FIG. 4 is a top down view of a portion of the light sheet of FIG. 1 showing the random locations of the LED dies after printing.

FIG. 5 illustrates the process for forming the extruded fluorescent substrate used in the light sheet of FIG. 1.

FIG. 6 illustrates an atmospheric pressure, roll-to-roll process used to form light sheets of any size and shape.

Elements that may be the same or equivalent in the various figures are labeled with the same numeral.

### DETAILED DESCRIPTION

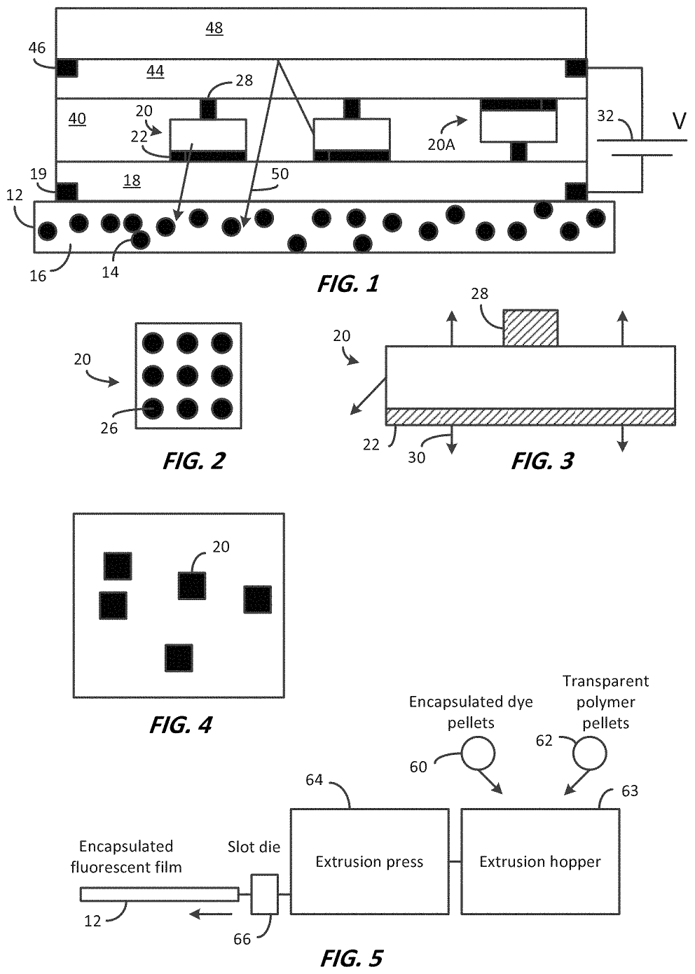

FIG. 1 illustrates one embodiment of the invention.

A thin substrate 12 is an extruded film having a thickness similar to that of a photographic negative, such as between 0.1-0.2 mm. Other thicknesses may be acceptable.

The substrate 12 comprises fluorescent crystals 14 embedded in a transparent plastic 16 and extruded as a substantially uniform mixture. The percentage by weight of crystals 14 and plastic 16 determines the density of the crystals 14 in the extruded substrate 12. Multiple color fluorescent materials, such as red, green, and blue, may be embedded in the plastic to achieve the desired overall emission color when energized with a blue or UV LED. YAG phosphor crystals (producing yellow light) will produce white light when combined with blue LED light.

Over the extruded substrate 12 is printed a thin, transparent conductive layer 18, such as sintered (after curing) silver nano-wires or other suitable layer. Such silver nano-wire (AgNW) ink is commercially available.

To improve electrical conduction of the transparent conductive layer 18, opaque metal busses 19 (or runners) may be printed before or after the transparent conductive layer 18 is printed. The busses 19 are interconnected and connected to a power source. The LEDs are not printed over the busses 19.

Over the transparent conductive layer 18 are printed micro-LEDs 20. The LEDs 20 are printed as a monolayer using, for example, lithography, screen printing, flexography, inkjet printing, gravure, or other printing techniques. Such printing may be prior art, such as using the techniques described in the assignee's U.S. Pat. No. 8,852,467, incorporated herein by reference.

Because of the comparatively low concentration of suspended LEDs in the ink solvent, such as alcohol, the LEDs 20 will be printed as a monolayer and be fairly uniformly distributed over the conductive layer 18.

The LED ink solvent is then evaporated by heat using, for example, an infrared oven. After curing, the LEDs 20 remain attached to the underlying conductive layer 18 with a small amount of residual resin that was dissolved in the LED ink as a viscosity modifier. The adhesive properties of the resin and the decrease in volume of resin underneath the LEDs 20 during curing press the bottom LED electrode 22 against the underlying conductive layer 18, making ohmic contact with it.

FIG. 2 is a bottom view of one type of LED 20 that may be printed. The structure of the LED 20 determines the orientation of the LED after being printed. An array of small metal dots 26 (relatively much smaller than shown in FIG. 2) is formed on the bottom of the LED die before the dies are segmented from an LED wafer. The dots 26 may be reflective (e.g., Al, Ag, etc.). The light generated by the active layer of the LEDs is fairly Lambertion, so about one-half the generated light is emitted from the bottom surface of the LED 20 between the dots 26.

FIG. 3 is a cross-sectional view of the LED 20 of FIG. 2. The top electrode 28 creates a fluid drag in the ink solvent, causing the bottom electrode 22 to electrically contact the conductive layer 18. The light 30 is emitted from the top, bottom, and sides of the LED 20. Although a majority of the LEDs 20 will have the correct orientation after printing, some of the LEDs 20 will have an improper orientation, as shown by the LED 20A in FIG. 1. In one embodiment, the power source 32 may be AC to cause both the proper and improper oriented LEDs to be alternately energized.

Next, a dielectric layer 40 is printed over the surface to encapsulate the LEDs 20 and further secure them in position. The top LED electrodes 28 are exposed, either by repelling the dielectric layer 40 or by using a blanket etch-back of the dielectric layer 40.

A top transparent or reflective conductive layer 44 is then printed over the dielectric layer 40 to electrically contact the electrodes 28 and is cured in an oven appropriate for the type of conductor being used. A transparent conductor layer may be sintered silver nano-wires, and a reflective conductive layer may be aluminum, silver, or alloys. The LEDs 20 are now electrically connected in parallel. Metal busses 46 may be used to improve the overall conductivity of the conductive layer 44.

If needed, a reflective layer 48 and/or a passivation layer may be printed or laminated over the top of the conductive layer 44.

The resulting light sheet is very flexible and may be rolled up in a roll-to-roll fabrication process.

When a proper polarity voltage is applied to the conductive layers 18 and 44, the LEDs 20 emit blue or UV light 50 to energize the fluorescent crystals 14 to cause them to emit a longer wavelength light, such as a mixture of red and green, or yellow, or a mixture of red, green, and blue. If the blue LED light is allowed to leak through, no blue wavelength fluorescent material is needed. The resulting thin sheet may emit white light or any other color in any emission pattern, determined by the printing process.

FIG. 4 is a top view of a small area of the light sheet showing the random distribution of the LEDs 20 due to the printing process.

The fluorescent substrate is formed by extrusion, as shown in FIG. 5. A fluorescent material, such as crystalized dyes, quantum dots, perovskite nano-crystals, or phosphors, is provided in small discrete pellets 60, such as having diameters of less than 3 mm. In one embodiment, the pellets 60 are cylindrical segments 1 mm thick and 3 mm long. Each pellet 60 includes the fluorescent material and possibly a transparent medium to encapsulate each crystal of the fluorescent material to form the pellet 60. A transparent binder, such as a plastic (e.g., polyester, polypropylene, PET, or other suitable material), is also provided as small pellets 62. The percentage of fluorescent material and plastic in the substrate 12 is determined by the weight ratios of the pellets.

A mixture of different type of fluorescent materials may be used to achieve various effects, such as a desired range of wavelengths and persistence.

In a preferred embodiment, the plastic used for the pellets 62 is a biaxially oriented PET (boPET), which resists shrinkage. Such boPET is available from Dupont, Kodak, Mitsubishi, and others.

Dye powder is commercially available for producing various products, and forming pellets of the powder, or pellets of the powder in a transparent binder, is within the skills of one skilled in the art of extrusion. One technique for crystalizing dyes is described in Plug-and-Play Optical Materials from Fluorescent Dyes and Macrocycles, by Benson et al., Volume 6, Issue 8, 6 Aug. 2020, Pages 1978-1997. A similar technique can be used to create the dye pellets 60. Using crystalized organic dyes in the pellets 60 is preferred over quantum dots and phosphors due to the higher quantum efficiency of the commercially available dyes. Perovskite nano-crystals also have a high quantum efficiency and can also be used.

The pellets 60 and 62 are then mixed in a hopper 63 and heated to create a uniform softened mixture. An extrusion press 64 then forces the mixture through a slot die 66 to create the thin fluorescent substrate 12 having very smooth surfaces and a uniform thickness. Thus, the emitted color will be uniform when the substrate 12 is energized with the LED light.

Companies that can produce the extruded fluorescent substrate 12 include Kodak, 3M, Performance Indicator LLC, and others.

By providing the substrate 12 as a fluorescent layer, there is no need for separate substrate and fluorescent layers, thus saving processing time and cost. Further, the fluorescent material is protected by a plastic coating for resistance to moisture and for providing heat dissipation. The plastic also provides a small distance between the fluorescent material and the LED surfaces, thus reducing the heat and primary light intensity applied to the fluorescent materials.

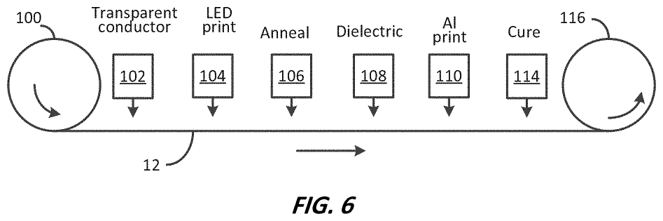

FIG. 6 illustrates a simplified fabrication process for forming wavelength-converted LED light sheets of any size, at atmospheric pressures, that emit white light for general illumination, such as for replacing fluorescent light fixtures in an office. Other overall emission colors may be created. A roll-to-roll process is shown.

A roll 100 of the thin flexible fluorescent substrate 12 is provided. The substrate 12 may be moved along the assembly line continuously or intermittently. A single process may be performed on the entire roll before the roll is subjected to the next process. FIG. 6 serves to show the various processes that may be performed on the substrate 12, rather than an actual assembly line. For example, the same printing tools may be used to deposit different inks at different stages of the process, rather than a different printing tool being used for each type of ink. So there may not be the various separate stations shown in FIG. 6.

At a first station 102, a transparent conductive ink is printed over the surface of the substrate 12 to form the conductive layer 18 (FIG. 1).

At a second station 104, the LED dies 20 are printed so that the bottom electrodes of the dies 20 make electrical contact with the conductive layer 18. In another embodiment, any type of LED may be printed, since the inventive fluorescent substrate is beneficial with a variety of types of LEDs.

At a third station 106, the layers are annealed/cured to fuse the LED dies' bottom electrodes to the conductive layer 18.

At a fourth station 108, the dielectric layer 40 is printed over the conductive layer 18.

At a fifth station 110, the transparent conductive layer 44 or a reflective aluminum conductor layer is printed over the top electrodes of the LED dies 20 to electrically connect groups of the LED dies, or all the printed LEDs, in parallel. Metal busses may also be printed to reduce the overall resistance of the current paths. The LEDs may be printed in any pattern, such as an alpha-numeric pattern or any other image.

At a sixth station 114, the resulting light sheet layers are cured.

The light sheet is then provided as a roll 116. The light sheets may be separated (cut) from the roll 116 at a later time and mounted in a fixture.

As seen, there is synergy in the substrate 12 being a fluorescent substrate since there is one fewer layer in the light sheet, the fluorescent material is protected by the plastic to extend the life of the fluorescent material, and the fluorescent material is more uniform over the LEDs.

Although the invention is described in the context of printing pre-formed micro LEDs, the LEDs may instead be printed layered structures, such as OLEDs, over the fluorescent substrate.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A method for forming a light emitting structure comprising:
extruding a mixture of a fluorescent material and a transparent plastic to form a flexible substrate;
providing a transparent first conductive layer over the substrate;
printing light emitting diodes (LEDs) over the first conductive layer;
providing a dielectric layer between the LEDs; and
providing a second conductive layer over the LEDs to electrically connect at least some of the LEDs in parallel, such that primary light emitted from the LEDs energizes the fluorescent material in the substrate to emit secondary light from the substrate.

2. The method of claim 1 wherein the step of printing LEDs comprises printing pre-formed inorganic micro-LEDs over the first conductive layer.

3. The method of claim 1 wherein the second conductive layer is reflective.

4. The method of claim 1 wherein the second conductive layer is transparent.

5. The method of claim 1 wherein the step of extruding comprises extruding a mixture of the fluorescent material and transparent plastic through a slot die.

6. The method of claim 1 wherein the fluorescent material is provided in first pellets, wherein the transparent plastic is provided in second pellets, the method further comprising mixing the first pellets and the second pellets prior to the step of extruding.

7. The method of claim 6 further comprising determining a weight percentage of the first pellets and the second pellets prior to mixing to obtain a desired density of the fluorescent material.

8. The method of claim 1 wherein the fluorescent material comprises a dye.

9. The method of claim 1 wherein the fluorescent material comprises perovskite crystals.

10. The method of claim 1 wherein the fluorescent material comprises a phosphor.

11. The method of claim 1 wherein the fluorescent material comprises quantum dots.

12. The method of claim 1 wherein the fluorescent material is provided in the first pellets along with a binder.

13. The method of claim 1 wherein the LEDs are printed so that their locations on the transparent first conductive layer are random as a result of printing.

14. The method of claim 1 wherein the LEDs have a structure to orient a majority of the LEDs in a desired manner on the transparent first conductive layer.

15. A light emitting structure comprising:
a flexible substrate formed by an extruded mixture of a fluorescent material and a transparent plastic;
a transparent first conductive layer over the substrate;
light emitting diodes (LEDs) over the first conductive layer;
a dielectric layer between the LEDs; and
a second conductive layer over the LEDs to electrically connect at least some of the LEDs in parallel, such that primary light emitted from the LEDs energizes the fluorescent material in the substrate to emit secondary light from the substrate.

16. The structure of claim 15 wherein the fluorescent material comprises at least one of a dye, perovskite crystals, a phosphor, or quantum dots.

17. The structure of claim 15 wherein the LEDs are printed so that their locations on the transparent first conductive layer are random as a result of printing.

18. The structure of claim 15 wherein the LEDs have a structure to orient a majority of the LEDs in a desired manner on the transparent first conductive layer when the LEDs are printed on the transparent first conductive layer.

19. The structure of claim 15 wherein the LEDs are inorganic micro-LEDs.
